(19) United States
(12) Patent Application Publication
(10) Pub. No.: US 2009/0242264 A1
(43) Pub. Date: Oct. 1, 2009

(54) Two piece shielding device

(75) Inventor: Gao-Bing Lei, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 12/383,495

(22) Filed: Mar. 25, 2009

(30) Foreign Application Priority Data
Mar. 25, 2008 (CN) 200820033114.6

(51) Int. Cl. H05K 9/00

(52) U.S. Cl. 174/382; 361/818

(57) ABSTRACT

A shielding device comprising: a metallic frame stamped from a sheet of metal material, the metallic frame having a top wall and sidewalls disposed along a periphery thereof, a central window defined on the top wall, a pair of interference pieces with a cutout extending therebetween and disposed on at least one of window side edges, the interference pieces adapted to extend away from central window, a metallic cap has a planar potion, and at least a pair of spaced spring legs extending from each side edge of the planar potion to elastically clamp the sidewalls of the metallic frame, each of spring legs having a resilient potion standably and elastically connected to free ends of spring legs, said resilient potion defining a shoulder edge below the interference pieces and a interference portion extending from the shoulder edge and into the cutout of the metallic frame.

### BACKGROUND OF THE INVENTION

1. Field of the invention

The present invention relates to a shielding device, and more particularly, to a shielding device configured with a metallic top removeably disposed onto a frame in which the metallic top can be readily removed therefrom for facilitating rework of electronic components enclosed therein, and then replaced with a new metallic top onto the frame after the rework is completed.

2. Description of Related Art

Electromagnetic interference is a problem which are frequently met which is very common in communication equipments, since the electromagnetic wave of a certain frequency is always radiated when the electric current pass the galvanic circle, if the said frequency level is close to or same with the other electrical components' frequency level, the working performance of electrical components will be affected, especially to the cell phones and other communication equipments which transmit signals by electromagnetic wave.

In order to eliminate the electromagnetic interference, a metallic frame is always disposed above or around the related electrical components of the communication equipments, the metallic frame can help to prevent the communication equipments from being affected from the electromagnetic interference, and release the static on the shielding device. Nowadays the metallic frames are always manufactured as two-pieces sets on account of the convenience of replacement of the electrical component. As shown in FIG. 1, a plurality of holes 51 are set on the frame 5, the cover 6 has dimples 61 which cooperate with the holes 51.

Unfortunately, problems continue to be encountered with the shielding device mentioned above. Because of the limitation of manufacturing process, it is difficult to control the machining precision of the dimples on the cover and the holes on the frame by stamping. The retention capability and the degree of stability between cover and frame can not be ensured. So the operational life of the shielding device is very short. Therefore, an improved shielding device is desired to overcome the disadvantages of the prior arts.

### SUMMARY OF THE INVENTION

An object, therefore, of the invention is to provide a new and improved shielding device of the character described able to ensure the stability between the cover and the frame, and to prolong the operational life of the shielding device.

In order to achieve the above-mentioned object, a shielding device adapted for preventing the electronic magnetic interference comprising: a metallic frame stamped from a sheet of metal material, the metallic frame having a top wall and sidewalls disposed along a periphery thereof, a central window defined on the top wall, a pair of interference pieces with a cutout extending therebetween and disposed on at least one of window side edges, the interference pieces adapted to extend away from said central window, a metallic cap assembled onto the metallic frame, the metallic cap stamped from a sheet of metal material, the metallic cap having a planar potion covering said central window of the metallic frame, and at least a pair of spaced spring legs extending from each side edge of the planar potion to elastically clamp the sidewalls of the metallic frame, each of spring legs having a resilient potion standably and elastically connected to free ends of spring legs, said resilient potion defining a shoulder edge below the interference pieces and a interference portion extending from the shoulder edge and into the cutout of the metallic frame.

Other objects, advantages and novel features of the present invention will become more apparent from the following detailed description of the present embodiment when taken in conjunction with the accompanying drawings.

### BRIEF DESCRIPTION OF THE DRAWINGS

FIG. 1 is an exploded view of the shielding device embodying the concepts of the prior art;

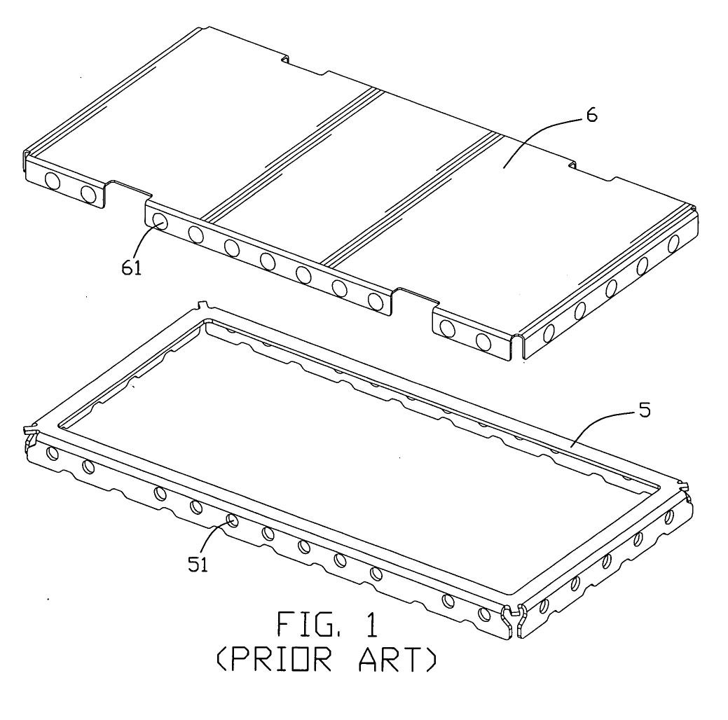

FIG. 2 is an assembled perspective view of a shielding device of the present invention;

FIG. 3 is an exploded, perspective view of the shielding device as shown in FIG. 2, viewed from another aspect; and

FIG. 4 is an exploded, perspective view of the shielding device as shown in FIG. 2, viewed from another aspect.

### DETAILED DESCRIPTION OF THE INVENTION

Reference will now be made in detail to the preferred embodiment of the present invention.

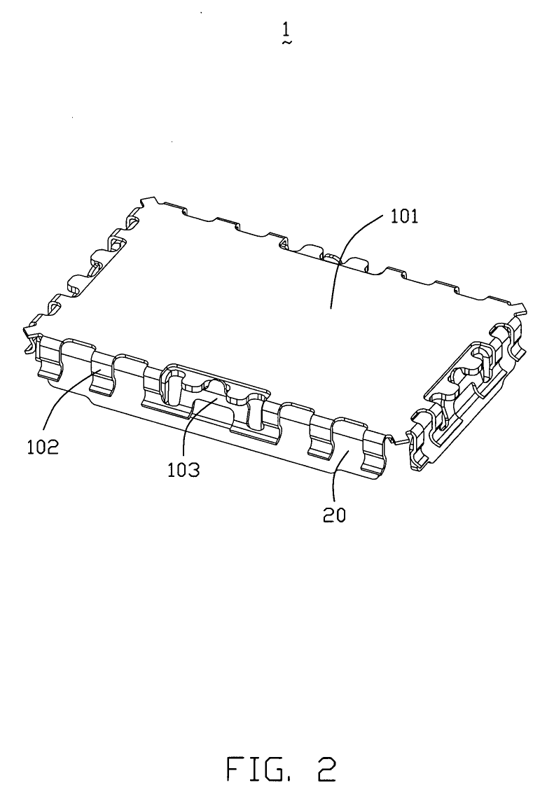

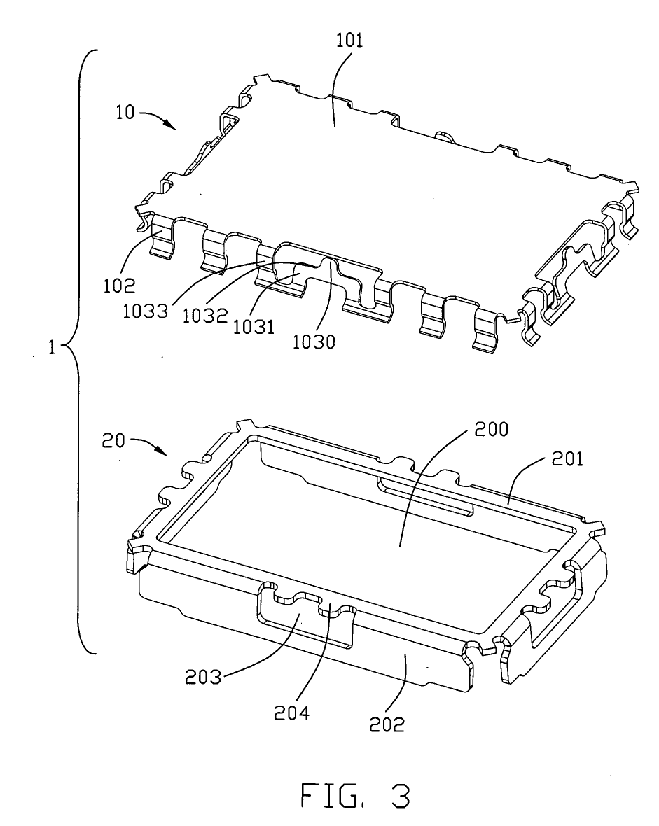

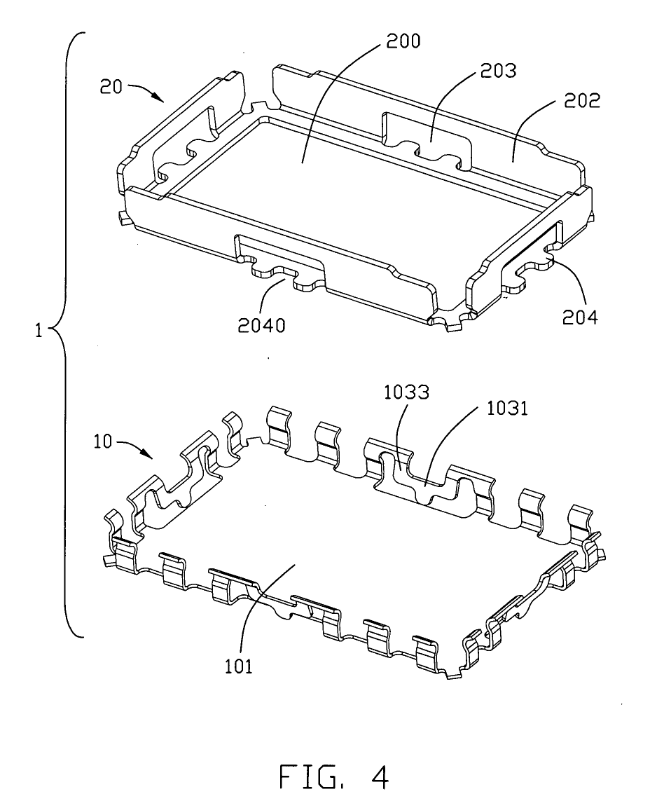

Referring to FIGS. 2-4, an embodiment of the present invention is illustrated. A shielding device 1 made in accordance with the present invention includes a metallic frame 20 with a metallic cap 10 removeably assembled thereto.

The metallic cap 10 includes a planar portion 101, which is made by a metallic sheet by stamping. The metallic cap 10 includes a retention portion 103 having an interferential portion 1030 and a resilient portion 1031. At least a pair of spring legs 1033 spaced from each other and each extends from one of opposite ends of the resilient portion 1031 to elastically clamp engage with the corresponding sidewall 202 of the metallic frame 20. A plurality of pushing arms are provided on each side edge of planar portion 101 with the free end of each pushing arm 102 cambered so as to provide a resilient clipping force. The resilient potion 1031 defines a shoulder edge 1032. The interference portion 1030 extends upwardly from the top shoulder edge 1032 of the resilient portion 1031, and the resilient portion 1031 is symmetrical to the interference portion 1030.

The metallic frame 20 includes a top wall 201 with four side edges extending downwardly thereof. A central window is defined on the top wall 201, and a sidewall 202 extends downwardly from the periphery of each side edge along the assembled direction of metallic cap 10 and metallic frame 20. The receiving space 200 is surrounded by the peripheral sidewalls 202 in order to receive various electronic components on printed circuit board. An opening 203 is defined through the sidewall 202. The interference pieces 204 extend to the direction away from the side edges or the central window, the middle part of the interference piece 204 forms a cutout 205 interferentially cooperating with the interference portion 1030 of the metallic cap 10.

In the process of assembly, firstly, bottom edges of the sidewall 202 of the metallic frame 20 is soldered on printed circuit board so as to securely attach the metallic frame 20 on the printed circuit board with the relative electronic components received within the receiving space 200 defined by the metallic frame 20. Afterwards, exerting a certain lateral and outward force on the interference portion 1030 of the metallic cap 10 to cause the spring legs 1033 elastically clamp the corresponding sidewall of the frame 20 so as to set up the engagement between metallic cap 10 and metallic frame 20. Meanwhile, the push arm 102 keeps a good and reliable resilient engagement with retention portion 103. In the process of metallic cap's assembly, the surface facing to the sidewall 202 of retention portion 103 always keeps a resilient touch with said interference piece 204 before assembly is completed.

After the assembly of the frame 20, the planar portion 101 of metallic cap 10 will cover the receiving space 200 of metallic frame 20. The push arm 102 keeps a resilient touch with the surface of sidewall 202. The interference portion 1030 of retention portion 103 is interferentially retained between the interference pieces 204 by the resilient portion 1031 keeping a certain elastic deformation all the time.

Generally, the cooperation between metallic cap 10 and metallic frame 20 can absorb the electromagnetic wave created by the electronic components to prevent the outside electromagnetic wave from affecting the working frequency of electronic components. When one or some of the said electronic components are out of order and need to be repaired, the metallic cap 10 can be readily removed. During repairing, a new metallic cap 10 would replace with the original metallic cap which has been removed; a new metallic cap 10 can be readily assembled to the frame 20 after the original metallic cap 10 removed.

While a preferred embodiment in accordance with the present invention has been shown and described, equivalent modifications and changes known to persons skilled in the art according to the spirit of the present invention are considered within the scope of the present invention as described in the appended claims.

What is claimed is:

1. A shielding device comprising:
a frame stamped from a sheet of metal material, the frame having a top wall and sidewalls disposed along a periphery thereof, a central window defined on the top wall, a pair of interference pieces with a cutout extending therebetween and disposed on at least one of window side edges, the interference pieces adapted to extend away from said central window,
a cap assembled onto the frame, the cap stamped from a sheet of metal material, the cap having a planar portion covering said central window of the frame, and at least a pair of spaced spring legs extending from at least one of side edges of the planar portion to elastically clamp the corresponding sidewall of the frame, a resilient portion standably and elastically connected to free ends of said spring legs, said resilient portion defining a shoulder edge below the interference pieces and a interference portion extending from the shoulder edge and into the cutout of the frame.

2. The shielding device as described in claim 1, wherein at least an opening is disposed on the sidewall.

3. The shielding device as described in claim 1, wherein at least a push arm extends from each side edge of planar portion.

4. The shielding device as described in claim 1, wherein the resilient portion is symmetrical to interference portion.

5. The shielding device as described in claim 3, wherein the ends of each push arms are cambered.

6. The shielding device as described in claim 1, wherein interference piece is configured to extend above the interference portion of the frame with a distance.

7. A metallic shielding device comprising:
a thinner upper part and a thicker lower part assembled together, said upper part essentially defining a complete top face and at least a resilient portion on one of four side faces, said lower part essentially defining four side walls and a top wall with a large central opening; wherein
said top wall defines, corresponding to and aligned with the resilient portion, a side opening in one side wall to form an interference piece on a top edge of said side opening so as to lock said resilient portion after the upper part is downwardly assembled to the lower part from the top wall.

8. The shielding device as claimed in claim 7, wherein said resilient portion defines an opening into which said interference piece extends.

9. The shielding device as claimed in claim 8, wherein a combination of said resilient portion and said interference piece is formed around each of said four side faces.
